(19) United States
(12) Patent Application Publication
(10) Pub. No.: US 2010/0002385 A1
(43) Pub. Date: Jan. 7, 2010

(54) ELECTRONIC DEVICE HAVING ACTIVE NOISE CONTROL AND A PORT ENDING WITH CURVED LIPS

(76) Inventors: Geoff Lyon, Menlo Park, CA (US); Ian N. Robinson, Pebble Beach, CA (US); Mehrban Jam, Fremont, CA (US)

Correspondence Address: HEWLETT-PACKARD COMPANY;Intellectual Property Administration, 3404 E. Harmony Road, Mail Stop 35, FORT COLLINS, CO, 80528, US

(21) Appl. No.: 12/249,633

(22) Filed: Oct. 10, 2008

Related U.S. Application Data
(60) Provisional application No. 61/078,016, filed on Jul. 3, 2008.

(51) Int. Cl. H05K 7/20

(52) U.S. Cl. 361/695

(57) ABSTRACT

An electronic device includes an enclosure for the electronic device and a fan to create an airflow for cooling electronic components contained in the enclosure. A port extends from an interior to an exterior of the enclosure and is arranged to allow airflow to pass therethrough, where the port comprises a port duct and an end having curved lips. An active noise control device detects a noise generated by the fan and generates an acoustic wave to reduce the noise.

### CROSS-REFERENCES

The present application claims priority from provisional application Ser. No. 61/078,016, filed Jul. 3, 2008, the contents of which are incorporated herein by reference in their entirety.

This application is related to copending and commonly assigned Provisional U.S. patent application Ser. No. TBD (Attorney Docket No. 200800523-1), entitled “Electronic Device Having Active Noise Control With An External Sensor,” filed by the same inventors to this instant patent application on TBD, the disclosure of which is hereby incorporated by reference in its entirety.

### BACKGROUND

Rotating devices, such as cooling fans and disk drives, in a computer system typically emit acoustic noise. Cooling fans in general generate a periodic noise known as a blade passing frequency (BPF), a noise that is generated at the tip of blades. An example of a conventional layout of rotating devices within a notebook computer is illustrated in FIG. 5, which includes a fan 510, a heatsink 520, and speakers 530.

The acoustic noise is often disturbing and has even been found to be damaging in environments such as datacenters, which contain many high performance fans. The acoustic noise has also been found to be highly distracting in quiet environments such as a home theater where a media computer is deployed.

A conventional way to remove fan noise has been through the use of passive noise control mechanisms. One conventional, passive noise control mechanism contains no fans, but instead, uses relatively large amounts of copper, heat pipes, heat sinks, etc. to adequately cool computer system components. However, due to the amount of materials required to implement the passive noise control mechanism, such a solution has often been expensive to implement.

Another conventional, passive noise control mechanism uses specially designed large and low-speed fans to shift the BPF into lower frequency bands, where the fan noise is less disturbing to the human ear. Still another conventional, passive noise control mechanism uses suitable noise absorbing materials and mounting components with suitable fasteners to reduce vibration and noise and thus avoid the so-called “tuning fork effect.” In general, the use of noise absorbing materials tends to be more effective at reducing higher frequency noise components, but less effective at eliminating lower frequency noise.

Yet another conventional way to passively control noise has been through careful selection and placement of individual components. For example, the use of low-noise cooling fans with precision low noise bearings and tuned blade shaping have become popular.

While the above-discussed conventional, passive noise control mechanisms are available, they are often costly and/or ineffective.

A further approach at reducing fan noise is through active noise control (ANC), which is a technique used to reduce noise and vibrations emanating from electronic devices, machinery, air ducts and other industrial equipment. An example of a conventional ANC system 100 is depicted in FIG. 1. As shown, the ANC system 100 includes a reference microphone 120 to detect a noise. The reference microphone is connected to control electronics 130, which is connected to a speaker 150. The speaker 150 provides anti-noise to reduce/counter the noise detected by the reference microphone 120. The ANC system 100 also includes an error microphone 140, which is used to detect the result of the noise-reduction and provides the detected result to the control electronics 130. The control electronics 130 may use the result received from the error microphone 140 to vary operation of the speaker 150 and further enhance noise reduction.

Conventional forms of ANC have been applied to certain consumer devices, the most popular being noise canceling headphones, where the external noise is reduced within the controlled zone of each ear-cup. Other applications where ANC has been applied include air-conditioning ducts, projectors, and large printers. However, in general, implementation of ANC in such systems is difficult because of the algorithmic complexity of the ANC and additional cost incurred with increases in the size of the enclosures housing the apparatuses. The more open the solution space and thus the size of the noise field being reduced, the less effective ANC becomes and the algorithmic complexity and costs also increase.

Although there have been recent attempts to reduce noise generated in electronic devices, such attempts have proven to be less than successful because the proposed solutions are either costly, bulky to implement, and/or ineffective.

### BRIEF DESCRIPTION OF DRAWINGS

The embodiments of the invention will be described in detail in the following description with reference to the following figures.

FIG. 1 illustrates a conventional ANC system;

FIG. 2A illustrates a cross-sectional side view of an inlet/outlet port according to an embodiment of the invention;

FIG. 2B illustrates a front view of the inlet/outlet port depicted in FIG. 2A;

FIG. 3A illustrates a cross-sectional side view of a duct forming an airflow passageway and having an ANC according to an embodiment of the invention;

FIG. 3B illustrates a cross-sectional top view of an electronic device with a duct connecting an inlet port and outlet port according to an embodiment of the invention;

FIG. 4A illustrates a e;

FIG. 4B illustrates a cross-sectional top view of a resonance cavity equivalent to a resonance cavity formed by the enclosure of the electronic device depicted in FIG. 4A;

FIG. 5 illustrates a conventional notebook computer;

FIG. 6 illustrates a cross-sectional top view of a notebook computer having an inlet port and an outlet port for airflow to pass through the notebook computer according to an embodiment of the invention;

FIG. 7A illustrates a cross-sectional top view of a notebook computer having two outlet ports for exhausting airflow from the notebook computer according to an embodiment of the invention;

FIG. 7B illustrates a side view of a notebook computer having two outlet ports located at the rear of the notebook computer according to an embodiment of the invention; and

FIG. 8 illustrates a flowchart of a method for using a port of an enclosure to allow airflow to pass through and performing an ANC according an embodiment of the invention.

### DETAILED DESCRIPTION OF EMBODIMENTS

For simplicity and illustrative purposes, the principles of the embodiments are described by referring mainly to examples thereof. In the following description, numerous specific details are set forth in order to provide a thorough understanding of the embodiments. It will be apparent, however, to one of ordinary skill in the art, that the embodiments may be practiced without limitation to these specific details. In some instances, well known methods and structures have not been described in detail so as not to unnecessarily obscure the embodiments.

Cooling fans in general generate a periodic noise known as a blade passing frequency (BPF). BPF is a noise that is generated at the tip of the fan blades. Cooling fans also generate a broadband noise that is mostly generated by consistent, laminar airflow noise. BPF is characterized by a distinctive high pitch whine and is generally the more annoying of the two noises. Once the BPF noise escapes into an open space outside the enclosure of electronic devices, it becomes very difficult to reduce/counter it. Thus, it is beneficial to have some control over the noise before it escapes from the electronic device enclosures.

Applying active noise control (ANC) in electronic devices, such as computers (for instance, desktop computers and notebook computers), enables use of relatively inexpensive commodity components to achieve the equivalent acoustic result of using more expensive passive component configurations. For example, according to an example, noise may be reduced by actively reducing the signature of the noise, for instance, the largest spectral components of the noise, as described in greater detail herein below.

ANC in general is more effective at reducing the higher BPF frequencies associated with small high speed fans typically employed in servers and high performance machines with space restrictions, but is generally less effective at reducing the broadband noise generated by the air rush noise. One reason for that is that noise canceling algorithms are typically more effective at reducing noises at higher frequencies.

However, unlike the ANC performed in noise canceling headphones, where noises come from outside and the noise reduction occurs in a small space, for instance, between the headphones and a user's ears, the implementation of ANC in computers with much larger internal spaces is relatively more difficult in terms of effectiveness and the required algorithms.

Disclosed herein are systems and methods that implement ANC in electronic devices in efficient, cost-saving and/or space-saving ways by using at least one of specially designed inlet/outlet ports, intermediate ducts connecting ports, a resonating chamber, and speaker(s). As also discussed herein, the speakers may be used to generate both anti-noise and user sounds.

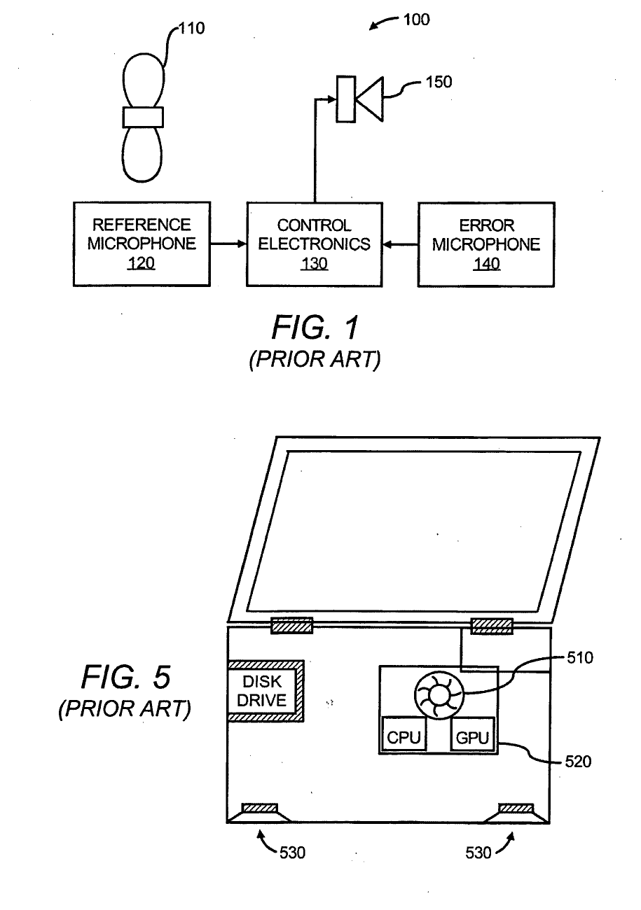

According to an example, a conventional ANC system, such as the ANC system depicted in FIG. 1, may be employed in an electronic device to reduce noise emanating from one or more rotating devices, such as, cooling fans, disk drives, etc., contained in the electronic device. More particularly, for instance, the fan 110 may be used to create an airflow for cooling components of an electronic device and may be a typical source of acoustic noise. In another example, another mechanism may be used to create an airflow and an element other than a fan, for instance, a disk drive, may be a typical source of acoustic noise. In any case, the reference microphone 120 may be located near or far from the source of noise and may capture the noise.

The error microphone 140 may detect the amount of combined fan noise and anti-noise generated by the speaker 150 and provide a signal corresponding to the combined amount, which corresponds to the differential between the noise and the anti-noise, as an error signal to the control electronics 130.

The reference microphone 120 and error microphone 140 may each be a microphone, vibration detector, or any other suitable device that detects a noise. In addition, the reference microphone 120 and error microphone 140 may each comprise one or more microphones, for instance, multiple condenser microphones configured as an array and connected in parallel for more precise noise capture. The order of the placement of the components, 110-150, in the ANC system 100 is not limited to that shown in FIG. 1 and may be rearranged in any combination and/or order without departing from a scope of the ANC system 100 depicted therein. For example, the error microphone 140 placement with respect to the fan 110 may be switched by making corresponding changes in the noise-canceling algorithms.

The speaker 150 may be a speaker, vibration generator, or any other wave generator configured to generate an acoustic wave, such as anti-noise, sound tone, etc., and to reduce/counter all or some of the undesirable fan noise.

The control electronics 130 may be any electronics that perform, implement, or execute one or more noise-canceling algorithms based on outputs from the reference microphone 120 and the error microphone 140. The noise-canceling algorithms may include the generation and output of a signal to the speaker 150 for generating an acoustic wave to reduce the noise. More particularly, for instance, the control electronics 130 analyzes the noise captured by the reference microphone 120 and the error microphone 140 and creates a signal for creation of an anti-noise to be played back through the speaker 150. Functions of the control electronics 130 may be performed in one unitary device or multiple devices. In addition, or alternatively, some or all of the functions of the control electronics 130 may be distributed to one or more of the other components, 120, 140 and 150.

According to an example, the error microphone 140 and the speaker 150 may be directly located next to the listener's ears as in noise canceling headphones. In another example, the error microphone 140 and the speaker 150 may be directly located at the electronic device, and the listener may be in a space further away from the error microphone 140 and the speaker 150. In the latter example, the control electronics 130 and acoustic properties of the electronic device may be designed to minimize the noise in the space surrounding the electronic device and not just at the location of the error microphone 140.

Although different reference numerals are recited in the following figures to designate reference microphones, error microphones, fans, speakers and control electronics, the above description with respect to FIG. 1 also applies to the reference microphones, error microphones, fans, speakers, and control electronics depicted in the following figures.

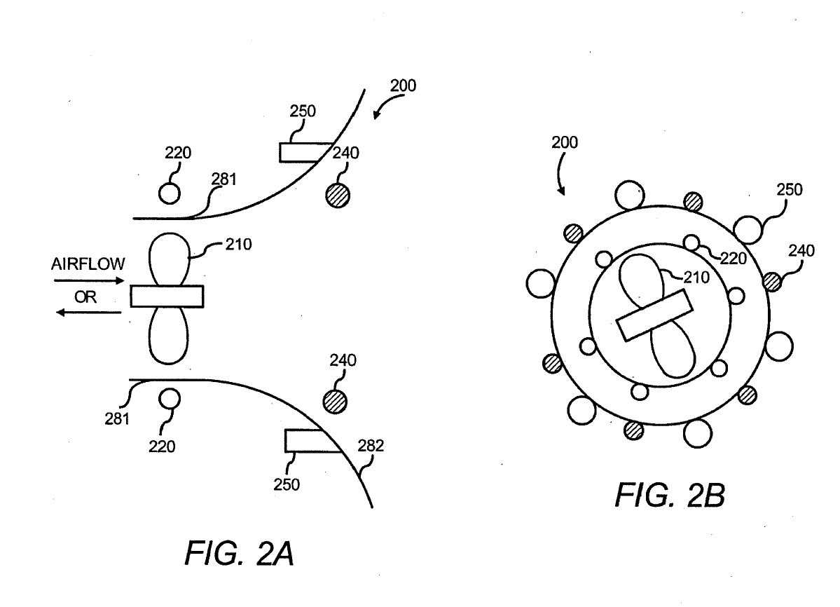

FIGS. 2A and 2B, respectively, illustrate a cross-sectional side view and a front view of an inlet/outlet port 200, according to an example. The port 200 may be positioned, for instance, at one or more interfaces between an interior and an exterior of an electronic device (not shown). Approximate positions of the reference microphone(s) 220, error microphone(s) 240 and anti-noise speaker(s) 250 with respect to the port 200 are shown in FIGS. 2A and 2B.

With reference first to FIG. 2A, the port 200 is shown as having a port duct 281 and ends 282, in which the ends 282 have curved lips. At least by virtue of the configuration of the duct 281 and the ends 282, air turbulence that would otherwise contribute to the broadband air rush noise is reduced. In one regard, the noise is reduced because the port duct 281 and the ends 282 do not contain sharp corners, which often create air turbulence and thus the air rush noise. According to an example, the port 200 may lack (or have a relatively small number of) sharp corners and may have a minimum amount of obstruction in the airflow path.

The duct 281 may comprise a straight pipe, slightly cone shaped pipe, or any other suitable shaped pipe that reduces the air turbulence through the duct 281. The curved lips of the ends 282 may expand uniformly and gradually as they grow out of the duct 281. Alternatively, however, the curved lips may have any other reasonably suitable configuration. Generally speaking, the curved lips of the ends 282 and the slight cone shaped configuration of the duct 281 reduce air speed and the amount of air turbulence at the enclosure opening, and thus the broad air rush noise at the enclosure opening. The port 200, if serving as an inlet port, may incorporate a fan 210 that pushes airflow into the enclosure to push air into the enclosure and counterbalance a limited number of inlet ports and outlet ports while maintaining the cooling efficiency of the enclosure.

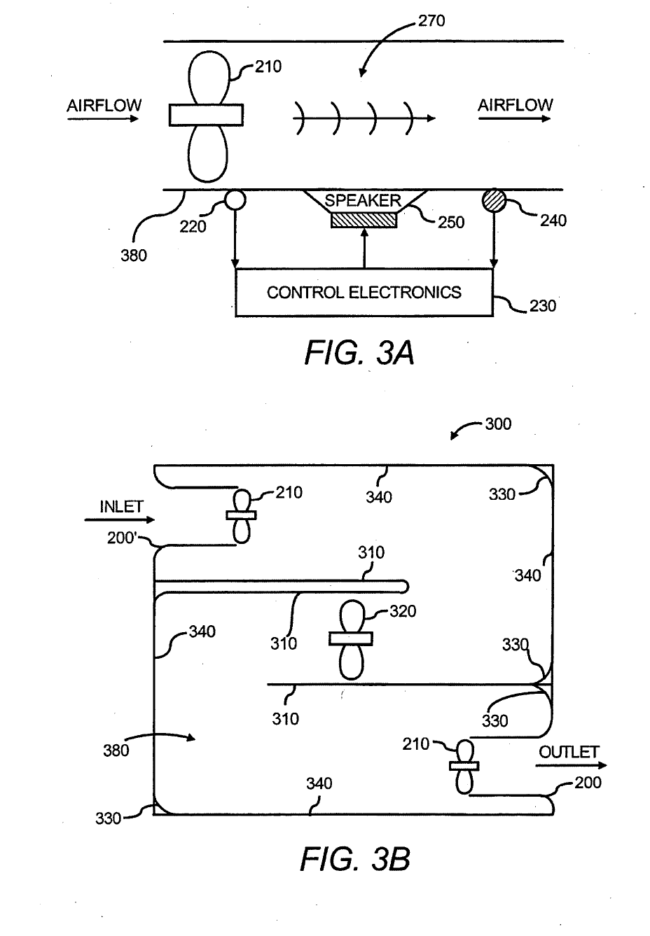

FIG. 3A illustrates a cross-sectional side view of a duct forming an airflow passageway and having an ANC according to an example: ANC may be more effectively applied when the noise, for instance, sound or vibration field, is ordered, confined or regulated to allow for better shaping of acoustic waves. Different shaping of a wave enclosure may cause the wave to behave in certain ways. For example, ANC may be more effectively and easily applied to a planar wave propagation than a three-dimensional propagation. In this regard, the duct 380 may be implemented to cause a noise to be propagated into a planar wave along the duct 380, as shown in FIG. 3A.

As also shown in FIG. 3A, noise reduction may be performed after the noise wave is shaped in a two dimensional wave-front as the result of traveling within the duct 380. According to an example, effective reduction may occur within the self contained enclosure depicted in FIG. 3A without the need for externally provided components prior to the wave propagating into a three dimensional space outside of the duct 380.

Specifically, when a noise created by the fan 210 travels through the duct 380, it propagates as a planar wave 270, which may be effectively and more easily reduced via ANC as described above. The fan 210 may comprise an internal fan positioned to direct heat away from a heat generating component, for instance. A reference microphone 220 detects the noise generated by the fan 210 and outputs a signal based on the noise to control electronics 230. The control electronics 230 outputs a signal to a speaker 250, which provides an anti-noise to reduce/counter the noise based upon the signal received from the control electronics 230. An error microphone 240 is used to detect the result of the noise-reduction and provides a signal corresponding to the detected result to the control electronics 230, which may use the detected result in varying the speaker 250 output.

FIG. 3B illustrates a cross-sectional top view of an electronic device 300 with a duct 380 connecting an inlet port 200′ and an outlet port 200, according to an example. Although not shown, the electronic device 300 may have one or more additional ports, where one or more of additional ports may comprise similar configurations as the ports 200.

The inlet port 200′ and outlet port 200 may each have a fan 210 to respectively push airflow into or pull airflow from an interior of the enclosure to compensate for increased air resistance due to a relatively restricted number of openings in the enclosure. Alternatively, one or more internal fans 320 may provide sufficient airflow through the intermediate duct, and one or more fans of the inlet or outlet ports 200 may be omitted.

The intermediate duct 380 may be formed by partition barriers 310 and enclosure walls 340. The partition barriers 310 create a relatively long path for noise to travel through in the enclosure. Although a single intermediate duct 380 has been depicted, it should be understood that the electronic device 300 may include any reasonably suitable number of intermediate ducts 380 without departing from a scope of the electronic device 300.

As shown, the corners 330 of the intermediate duct 380 may be rounded to form curved corners, which generally reduce air turbulence. By use of the intermediate duct 380 with the curved corners 330, internal noise, such as noise emanating from a cooling fan for a central processing unit (CPU) must travel along the intermediate duct, which shapes the noise wave-front to be more like a planar wave propagation and more suitable for application of ANC at one or both of the inlet and outlet ports 200.

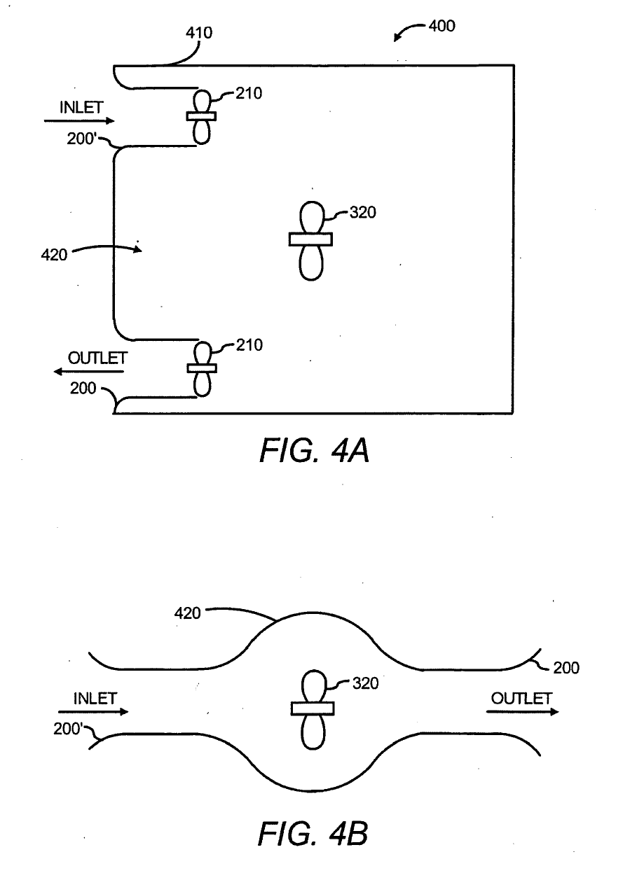

FIG. 4A illustrates a cross-sectional top view of an electronic device 400 having an inlet port 200′ and an outlet port 200, according to another example. At least one of the ports may be a port other than the port 200 having an end with curved lips. The electronic device 400 has an enclosure 410 without partition barriers, and instead, a resonance cavity 420 has been formed inside the enclosure 410. By utilizing the resonance cavity 420 formed by the enclosure 410, selected one or more frequency components of the noise may be amplified and reduced through application of ANC, and other frequency components of the noise may be randomized and attenuated.

FIG. 4B illustrates a cross-sectional top view of a resonance cavity 420 equivalent to a resonance cavity formed by the enclosure 410 of the electronic device 400 depicted in FIG. 4A. The resonance cavity 420 may be similar, more or less, to a Helmholtz resonance cavity.

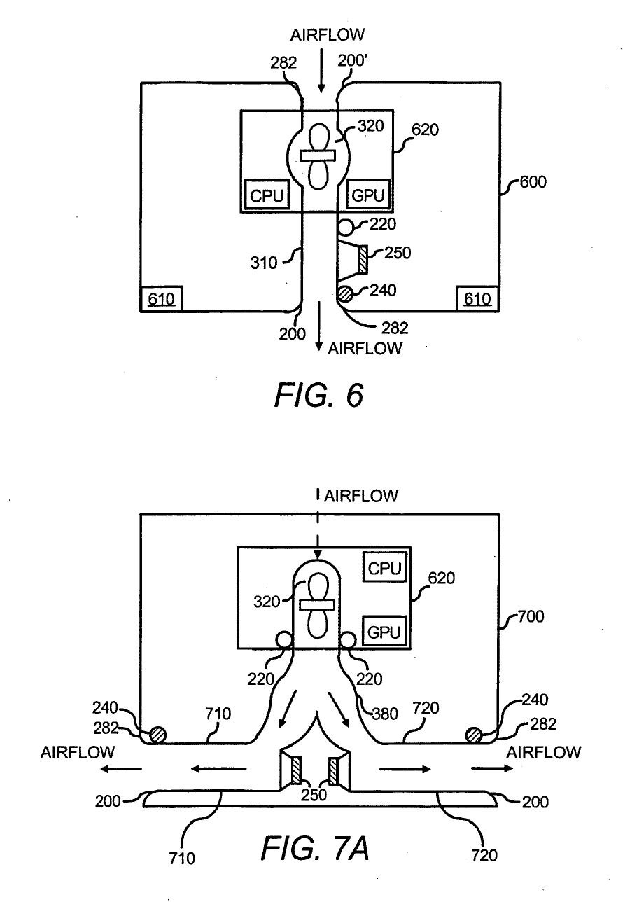

FIG. 6 illustrates a cross-sectional top view of a notebook computer 600 having an inlet port 200′ and an outlet port 200 for airflow to pass through the notebook computer 600, according to an example. Although both the inlet port 200′ and the outlet port 200 have been depicted as having ends 282 with curved lips, it should be understood that one of the inlet port 200′ and the outlet port 200 may have the ends 282 and the other one may have a conventionally shaped end.

In any regard, airflow enters the notebook computer 600 through an inlet port 200′ in a rear of the notebook computer 600. As shown, a cooling fan 320 is operable to cause airflow to be drawn into the notebook computer 600. In addition, the cooling fan 320 may be located at or near a source of maximum heat dissipation, which may be near the CPU and the graphics processing unit (GPU) of the notebook computer 600. In addition, the cooling fan 320 may be positioned to dissipate heat from a heat sink 620 which aids in dissipating heat from the CPUs and GPUs. A simple closed-loop-thermostat-driven circuit or closed-loop-thermometer-driven circuit may control the on/off state of the cooling fan 320 in response to changes in the temperature of the heat sink 620. The cooling fan 320 may force an airflow from the inlet port through the intermediate duct formed by internal partitions 310 (FIG. 3B), which passes over the heatsink 620 to which the CPU and the GPU are thermally connected. Heat is transferred from CPU and GPU, via the heatsink 620, to the forced airflow, which escapes from the notebook computer 600 via the outlet port 200.

ANC may be implemented around at least one of the ports 200. The ANC may have minimum necessary components including, one reference microphone 220, one error microphone 240 and one anti-noise speaker 250. Alternatively, the outlet port 200 and any other port with ANC may have multiple microphones and/or speakers, and the intermediate duct may be more curved than as depicted in FIG. 6.

The anti-noise speaker 250 is generally operated to generate an acoustic wave to reduce the noise generated by the fan 320. In addition, the anti-noise speaker 250 may also purposefully generate user sounds (for instance, music from a compact disk or a system sound generated by the computer to alert the user). Such use of the anti-noise speaker 250 to generate both the anti-noise and the user sounds obviates a need for another speaker for generating one of the two sounds, allows the implementation of both features to occupy less overall space, and saves component costs, when compared with using two separate speakers.

According to an example, the anti-noise speaker 250 may also purposefully generate lower, bass frequency user sounds. An improved bass response for the speaker system may be obtained since the speaker 250 is ported inside the computer. In this example, two smaller speakers 610 may be positioned in the left and right front corners of the notebook computer 600, for instance, to generate higher, treble frequency user sounds.

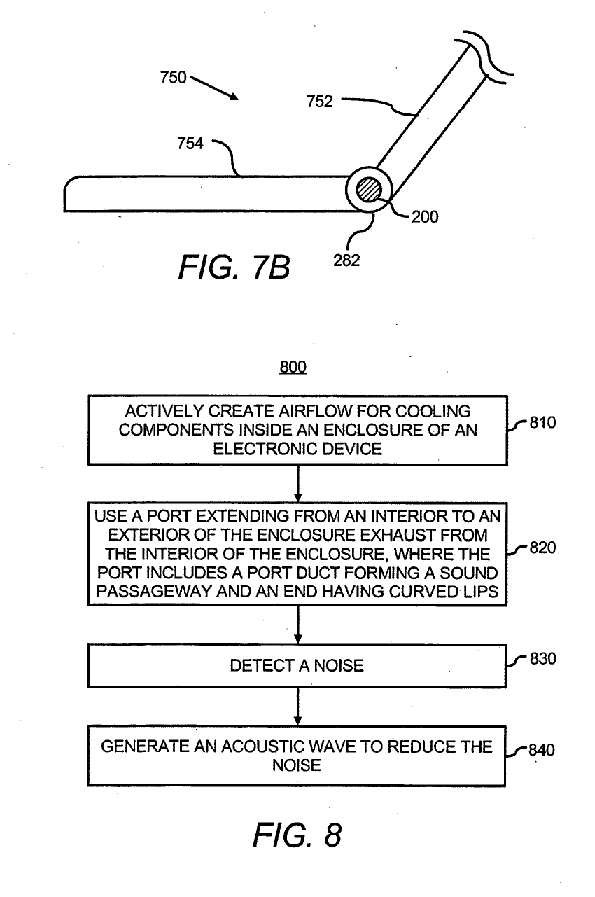

FIG. 7A illustrates a cross-sectional top view of a notebook computer 700 having two outlet ports 200 for exhausting airflow from the notebook computer 700, according to another example. At least one or more of the outlet ports and the inlet port may be a port other than the port 200 having ends with curved lips, and the inlet port may also comprise ends 282 having curved lips. The notebook computer 700 shown in FIG. 7A may be a consumer or multi-media notebook computer and may be larger than the notebook computer 600 shown in FIG. 6.

As shown, the inlet port 200′ is positioned on a bottom side of the notebook computer 700. In addition, the notebook computer 700 includes two intermediate ducts 710 and 720 configured to direct exhaust airflow out of the notebook computer 700. Respective ends of the intermediate ducts 710 and 720 may comprise outlet ports 200, which are depicted as being positioned on opposite sides of the notebook computer 700. Heat generated by the electronic components (CPU, GPU, etc.) is transferred to the airflow and caused to exit from the notebook computer 700 through the outlet ports 200.

Airflow from the cooling fan 320 flows through an intermediate duct 380, which is split into a left intermediate duct 710 and a right intermediate duct 720. A left speaker 250 is positioned to supply anti-noise acoustic waves into the left intermediate duct 710, and a right speaker 250 is positioned to supply anti-noise acoustic waves into the right intermediate duct 720. The speakers 250 may also be configured to generate user sounds in stereo by allowing left and right audio channels to be separately outputted. In this regard, the anti-noise speakers 250 may be implemented to provide stereo sound, and thus, the notebook computer 700 may not need a separate set of speakers to provide the stereo sound.

According to an example, independent ANC algorithms may be applied for the ANC performed in each of the left and right intermediate ducts 710 and 720. Alternatively, ANC algorithms applied for the ANC performed in the left intermediate duct 710 may be correlated to ANC algorithms applied for the ANC performed in the right intermediate duct 720.

FIG. 7B illustrates a side view of a notebook computer 750 having two outlet ports 200 located at the rear of the notebook computer 750, according to an example. The notebook computer 750 includes a lid 752 and a base 754. The outlet ports 200 may comprise ends 282 having curved lips and an inlet port 200′ positioned, for instance, below the base 754, which may also comprise an end 282 having curved lips. The same components, 220, 240, 710, 720, and 200, and their arrangement in FIG. 7A may be used in FIG. 7B, except that their orientation in the computer shown in FIG. 7B is reversed, that is, back to front inside the computer, so that the outlet port 200 is located at the rear of the computer as shown in FIG. 7B.

As shown in FIG. 7B, two intermediate ducts are routed through the computer base 754 at the rear of the computer 750 and are connected to respective outlet ports 200 on the side edges of the computer base 754. In addition, the rear of the notebook computer 750, where the base 754 and the lid 752 are hinged together, may have an increased height with respect to the front of the base 754 to thus allow for greater space in implementing the intermediate ducts 710, 720 and the outlet ports 200.

The examples shown in FIGS. 6, 7A, and 7B should be construed as merely being exemplary, and other configurations for implementing ANC within a scope of the present invention in notebook computers are also possible. For example, a complete separation between the left and right stereo audio channels and ducts may be applied to form completely independent ducts and thus audio channels formed thereby, to, for instance, allow separation and more flexible positioning of the two primary heat source components (i.e., CPU and GPU) and thus allow independent control of their cooling and noise control.

Although the duct, speaker and port arrangements of FIGS. 6, 7A, and 7B have been explained in connection with notebook computers, the same duct and port arrangements shown in FIGS. 6, 7A, and 7B may be applied to desktop computers as well as other electronic devices, such as, stereo systems, projectors, televisions, refrigerators, etc.

FIG. 8 illustrates a flowchart of a method 800 for using a port of an enclosure to allow airflow to exhaust from an interior of the enclosure and reduce noise generated in the enclosure, according an example. It should be apparent to those of ordinary skill in the art that other steps may be added or existing steps may be removed, modified or rearranged without departing from a scope of the method 800.

At step 810, airflow for cooling components inside an enclosure for an electronic device is actively created, through, for instance, operation of a cooling fan 320.

At step 820, a port extending from an interior to an exterior of the enclosure is used to allow the airflow to exhaust from the interior of the enclosure, where the port comprises a port duct forming a sound passageway and an end having curved lips.

At step 830, a noise, for instance, generated by operation of the cooling fan 320 is detected. In addition, at step 840, an acoustic wave to reduce the noise is generated.

In connection with the method 800, partition barriers 310 (FIG. 3B) may be used inside the enclosure to form an intermediate duct 380 connecting an inlet port 200′ to an outlet port 200 of the enclosure. Corners of the intermediate duct 380 may also be curved as discussed above with respect to FIG. 3B. In addition, a resonance cavity may be used inside the enclosure to amplify and reduce at least one selected frequency component of the noise and randomize and attenuate non-selected frequency components of the noise. Also, a speaker may be used to generate both the wave to reduce the noise and purposefully generate user sounds.

Any one or all of the exemplary features and embodiments of the invention may be applied and is incorporated in any and all of the embodiments of the invention unless clearly contradictory.

Further, in each of the exemplary embodiment of the invention described above, any one or more of the following additional measures may be taken to reduce noise further.

For instance, passive noise control mechanisms such as vibration/noise reducing foams may be used in critical places to improve noise-performance. Also, low speed fans producing BPF below human sensitivity may be used. Specifically, in applying the ANC, fan's rotational speed may be controlled by, for example, pulse-width-modulating a drive signal to the fan, to provide a particular harmonic signature, that is the largest spectral components, to the noise the fan generates. By doing so, the noise may be provided with a known expected signal characteristic for which there is an effective noise-canceling algorithm. Also, the fan's rotational speed can be controlled to provide a noise with components that self-cancel or a noise without certain frequencies that are prone to resonance or are particularly difficult to cancel.

While the embodiments have been described with reference to examples, those skilled in the art will be able to make various modifications to the described embodiments without departing from the scope of the claimed embodiments.

What is claimed is:

1. An electronic device comprising:
an enclosure for the electronic device;
a fan to create an airflow for cooling electronic components contained in the enclosure;
a port extending from an interior to an exterior of the enclosure and arranged to allow airflow to pass therethrough, wherein the port comprises a port duct and an end having curved lips; and
an active noise control device to detect a noise generated by the fan and to generate an acoustic wave to reduce the noise.

2. The electronic device of claim 1, further comprising:
an inlet port and an outlet port in the enclosure; and
partition barriers inside the enclosure to form an intermediate duct connecting the inlet port to the outlet port.

3. The electronic device of claim 2, wherein the intermediate duct formed by the partition barriers have bent sections formed with curves to reduce air turbulence in the intermediate duct.

4. The electronic device of claim 1, wherein the enclosure forms a resonance cavity to amplify and reduce at least one selected frequency component of the noise and randomize and attenuate non-selected frequency components of the noise.

5. The electronic device of claim 1, wherein the active noise control device comprises a speaker to generate the acoustic wave to reduce the noise, and wherein the speaker is also configured to purposefully generate user sounds.

6. The electronic device of claim 5, further comprising:
a second port extending from an interior to an exterior of the enclosure, wherein the second port comprises a second port duct forming a sound passageway and an end having curved lips; and
a second active noise control device to detect a noise generated by a fan and to generate an acoustic wave to reduce the noise, wherein the ends of the first and second ports are on different sides of the enclosure.

7. An electronic device comprising:
an enclosure for the electronic device, the enclosure having an inlet port and an outlet port, wherein at least one of the inlet port and the outlet port extends from an interior to an exterior of the enclosure and comprises a port duct forming a sound passageway and an end having curved lips;
partition barriers inside the enclosure to form an intermediate duct connecting the inlet port to the outlet port; and
an active noise control device to detect a noise generated in the intermediate duct and to generate an acoustic wave to reduce the noise.

8. The electronic device of claim 7, further comprising a mechanism other than the active noise control device to reduce the noise.

9. The electronic device of claim 7, wherein the active noise control device comprises a speaker to generate both the acoustic wave to reduce the noise and purposefully generate user sounds.

10. The electronic device of claim 9, further comprising:
a second port extending from an interior to an exterior of the enclosure, wherein the second port comprises a second port duct forming a sound passageway and an end having curved lips; and
a second active noise control device to detect a noise and to generate an acoustic wave to reduce the noise, wherein the first and second ports exhaust airflow to opposite sides of the enclosure.

11. A method comprising:
actively creating airflow for cooling components placed inside an enclosure for an electronic device;
using a port extending from an interior to an exterior of the enclosure to allow the airflow to exhaust from the interior of the enclosure, wherein the port comprises a port duct forming a sound passageway and an end having curved lips;
detecting a noise; and
generating an acoustic wave to reduce the noise.

12. The method of claim 11, further comprising using partition barriers inside the enclosure to form an intermediate duct connecting an inlet port to an outlet port of the enclosure.

13. The method of claim 12, further comprising using curves in bent sections of the intermediate duct.

14. The method of claim 11, further comprising using a resonance cavity inside the enclosure to amplify and reduce at least one selected frequency component of the noise and randomize and attenuate non-selected frequency components of the noise.

15. The method of claim 11, further comprising using a speaker to generate both the acoustic wave to reduce the noise and purposefully generated user sounds.
